(19) United States
(12) Patent Application Publication
(10) Pub. No.: US 2026/0344219 A1
(43) Pub. Date: Oct. 29, 2026

(54) DISPLAY APPARATUS

(71) Applicant: LG Display Co., Ltd., Seoul (KR)

(72) Inventor: Yoonjong LEE, Paju-si (KR)

(73) Assignee: LG Display Co., Ltd., Seoul (KR)

(21) Appl. No.: 19/640,295

(22) Filed: Apr. 6, 2026

(30) Foreign Application Priority Data
Apr. 29, 2025 (KR) 10-2025-0056475

(51) Int. Cl. H10K 59/131

(52) U.S. Cl. CPC H10K 59/131

(57) ABSTRACT

A display apparatus includes a first substrate including a display area and a non-display area disposed outside the display area. A bonding pad area is disposed in the non-display area, and a second substrate is disposed on the bonding pad area of the first substrate. A first alignment mark is disposed on the second substrate. A second alignment mark is disposed on the bonding pad area of the first substrate and is positioned to overlap the first alignment mark in a vertical direction. The first alignment mark includes a plurality of protruding patterns. The plurality of protruding patterns are configured to be deformed during a bonding process so that alignment between the second substrate and the first substrate can be inspected based on deformation of the plurality of protruding patterns.

### CROSS-REFERENCE TO RELATED APPLICATION

This application claims priority from Republic of Korea Patent Application No. 10-2025-0056475 filed on Apr. 29, 2025, which is hereby incorporated by reference its entirety.

### BACKGROUND

### Technical Field

The present disclosure relates to a display apparatus.

### DESCRIPTION OF RELATED ART

The contents described in this section merely provides background information on the present disclosure and does not constitute the prior art.

The display apparatus is applied to various electronic devices such as a TV, a smartphone, a laptop computer, and a tablet. To this end, research is being conducted to develop a thin, light weight, and low power consuming display apparatus.

The display apparatus may include a display panel including a screen displaying information, a driving circuit for driving the display panel, a driving circuit chip package, a printed circuit board, etc. The driver may include a scan driver for supplying a scan signal (or a gate signal) to the display panel, a data driver for supplying a data signal to the display panel, etc.

The printed circuit board may include various electronic components that provide signals or voltages for driving the display panel. A signal or a voltage provided from the printed circuit board may be provided to the display panel via the driving circuit chip package. Each of the driving circuit chip package and the printed circuit board may be connected to the display panel using a bonding process.

### BRIEF SUMMARY

A scheme of coupling the driving circuit chip and the display panel to each other may vary depending on a type of a substrate on which the driving circuit chip is mounted. For example, the scheme of coupling the driving circuit chip and the display panel to each other may include a COG (Chip on glass) scheme, a COF (Chip on film) scheme, a COP (Chip on plastic) scheme, etc.

The driving circuit chip package or the printed circuit board may be mounted on the display panel using bonding equipment in a tape automated bonding (TAB) scheme. For example, a chip pad of the driving circuit chip package and a bonding pad of the display panel may be coupled to each other in a bonding manner.

Each of the driving circuit chip package and the display panel is an independent unit. Accordingly, in order to prevent a contact and connection failure between the independent units from occurring, alignment between the driving circuit chip package and the display panel should be maintained within a set range.

As one of the schemes of evaluating whether the alignment therebetween is within the set range, a scheme of inspecting the parallelism by placing a pressure-sensitive film between a bonding tool of the bonding equipment and a backup stage opposite to and facing the bonding tool may be considered. However, in the scheme using the pressure-sensitive film, the visual inspection is performed such that there is a problem in that the inspection accuracy is poor and it is difficult to realize quantitative evaluation.

Accordingly, through various experiments, the present disclosure provides a display apparatus including alignment patterns configured to inspect whether alignment between a driving circuit chip package and a display panel is within a set range.

Various embodiments of the present disclosure provide a display apparatus capable of inspecting an alignment accuracy between a display panel and a driving circuit chip.

In addition, various embodiments of the present disclosure provide a display apparatus capable of measuring an alignment accuracy between a display panel and a driving circuit chip and accurately inspecting whether there is a contact and connection failure based on the measured alignment accuracy.

In addition, various embodiments of the present disclosure provide a display apparatus capable of measuring an alignment accuracy between a display panel and a driving circuit chip and measuring a parallelism between a bonding tool of bonding equipment and a backup stage based on the measured alignment accuracy.

In addition, various embodiments of the present disclosure provide a display apparatus capable of preventing a contact and connection failure between a display panel and a driving circuit chip from occurring using a structure for measuring the alignment accuracy therebetween, thereby reducing production energy and reducing greenhouse gas emission.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display apparatus according to an embodiment of the present disclosure includes: a first substrate including a display area and a non-display area disposed outside the display area; a bonding pad area disposed in the non-display area; a second substrate disposed on the bonding pad area of the first substrate; a first alignment mark disposed on the second substrate; and a second alignment mark disposed on the bonding pad area of the first substrate and positioned to overlap the first alignment mark in a vertical direction, wherein the first alignment mark includes a plurality of protruding patterns.

In the display apparatus according to an embodiment of the present disclosure, the alignment accuracy may be measured using the alignment marks disposed on each of the display panel and the driving circuit chip, such that whether there is a contact and connection failure therebetween may be accurately inspected compared to when inspecting the alignment accuracy in the visual inspection manner.

In addition, in the display apparatus according to an embodiment of the present disclosure, the alignment accuracy may be measured using the alignment marks disposed on each of the display panel and the driving circuit chip, such that the parallelism between the bonding tool of the bonding equipment and the backup stage opposite to and facing the bonding tool may be evaluated in a quantitative value.

In addition, in the display apparatus according to an embodiment of the present disclosure, the parallelism between the bonding tool of the bonding equipment and the backup stage opposite to and facing the bonding tool may be evaluated in a quantitative value using the alignment marks disposed on each of the display panel and the driving circuit chip, thereby improving the bonding quality therebetween.

In addition, in the display apparatus according to an embodiment of the present disclosure, the alignment accuracy may be measured using the alignment marks disposed on each of the display panel and the driving circuit chip, thereby preventing a contact and connection failure between the display panel and the driving circuit chip from occurring. Accordingly, there is an effect that the contact and connection failure of the product is reduced, so that production energy may be reduced and greenhouse gas emission may be reduced.

The effects of the present disclosure are not limited to the effects as mentioned above, and other effects not mentioned will be clearly understood by those skilled in the art from the following descriptions.

### BRIEF DESCRIPTION OF THE SEVERAL VIEWS OF THE DRAWINGS

FIG. 1 is an exploded perspective view of a display apparatus according to an embodiment of the present disclosure.

FIG. 2 is a plan view of a display panel according to an embodiment of the present disclosure.

FIG. 3 is a cross-sectional view according to an embodiment of the present disclosure.

FIG. 4 is a cross-sectional view taken along a line II-II′ of FIG. 2.

FIG. 5 is an enlarged view of a driving circuit chip package according to an embodiment of the present disclosure.

FIG. 6 is a diagram illustrating a partial area in which a display panel and a driving circuit chip package are coupled to each other according to an embodiment of the present disclosure.

FIGS. 7 and 8 are diagrams illustrating a first alignment mark according to an embodiment of the present disclosure.

FIG. 9 is a diagram illustrating a first alignment mark according to another embodiment of the present disclosure.

FIGS. 10 and 11 are enlarged views of an area III of FIG. 6.

FIGS. 12 and 13 are diagrams illustrating a display apparatus before and after a bonding process between a first substrate and a second substrate according to an embodiment of the present disclosure.

FIGS. 14 and 15 are diagrams illustrating a scheme of measuring a parallelism using alignment marks according to an embodiment of the present disclosure.

FIGS. 16 and 17 are diagrams illustrating a scheme of measuring a parallelism using alignment marks according to another embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure as defined by the appended claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers.

It will be understood that when an element or layer is referred to as being “connected to”, or “connected to” another element or layer, it may be directly on, connected to, or connected to the other element or layer, or one or more intervening elements or layers may be present.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on top” of another layer, film, region, plate, or the like, the former may directly contact the latter or still another layer, film, region, plate, or the like may be disposed between the former and the latter. As used herein, when a layer, film, region, plate, or the like is directly disposed “on” or “on top” of another layer, film, region, plate, or the like, the former directly contacts the latter and still another layer, film, region, plate, or the like is not disposed between the former and the latter. Further, as used herein, when a layer, film, region, plate, or the like is disposed “under” another layer, film, region, plate, or the like, the former may directly contact the latter or still another layer, film, region, plate, or the like may be disposed between the former and the latter. As used herein, when a layer, film, region, plate, or the like is directly disposed “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship with each other.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In description of flow of a signal, for example, when a signal is delivered from a node A to a node B, this may include a case where the signal is transferred from the node A to the node B via another node unless a phrase ‘immediately transferred’ or ‘directly transferred’ is used.

The disclosure describes a display apparatus that incorporates a built-in bonding evaluation structure at the interface between a display panel and a driving circuit chip package. A first alignment mark is positioned on the substrate of the driving circuit chip package, and a second alignment mark is positioned on the bonding pad area of the display panel substrate so that the two marks overlap vertically. The first alignment mark includes multiple protruding patterns, allowing the bonded assembly to provide measurable information related to alignment accuracy and bonding quality.

Unlike conventional fiducial marks used only for placement, the chip-side alignment mark includes protrusions that deform under bonding pressure and can be measured after bonding. In certain implementations, the protrusions are arranged on an alignment plate at four corner locations, optionally with an additional protrusion at the center. The panel-side alignment mark may have a ring-shaped pattern that surrounds the chip-side mark in plan view. Measurements of protrusion deformation or the spacing between the two marks can be used to evaluate alignment and the parallelism between the bonding tool and the backup stage.

Additional structural aspects include placing multiple mark pairs at different positions such as corner and center regions of the chip package to detect tilt or uneven pressure during bonding. The protrusions may include a relatively rigid core with a ductile cover layer so that controlled flattening occurs during pressing. The height of the alignment mark may also be limited so that it does not interfere with electrical bonding between chip pads and bonding pads. Together, these features enable quantitative inspection of bonding alignment and process conditions within the assembled display structure.

Hereinafter, a display apparatus according to each embodiment of the present disclosure will be described with reference to the accompanying drawings.

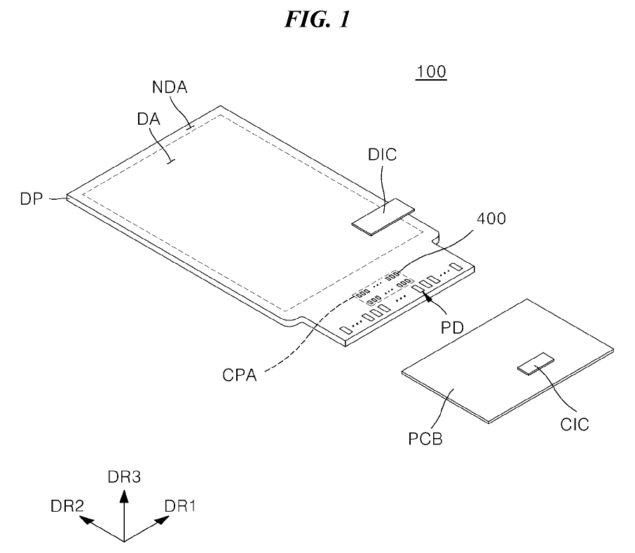

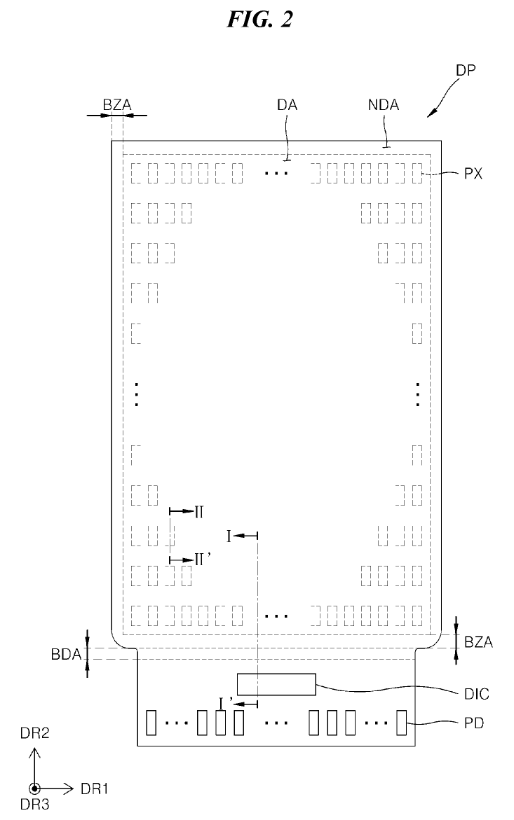

FIG. 1 is an exploded perspective view of a display apparatus according to an embodiment of the present disclosure. FIG. 2 is a plan view of a display panel according to an embodiment of the present disclosure.

Referring to FIGS. 1 and 2, the display apparatus may include a display panel DP, a driving circuit chip package DIC, a printed circuit board PCB, and a control circuit chip CIC.

The display panel DP may include a plurality of sub-pixels PX, a plurality of bonding pads 400, and a plurality of contact and connection pads PD. The plurality of sub-pixels PX may be disposed in the display area DA of the display panel DP, and the plurality of bonding pads 400 and the plurality of contact and connection pads PD may be disposed in the non-display area NDA.

The display area DA may be an area in which an image is displayed. The non-display area NDA may be an area in which no image is displayed. The non-display area NDA may be positioned in a peripheral area (or an edge area) of the display panel DP. However, embodiments of the present disclosure are not limited thereto. For example, a remaining area except for the light-emission area in which light is emitted to the outside in the display area DA may be referred to as the non-display area NDA. A bezel area BZA of the display panel DP may be defined in the non-display area NDA. The bezel area BZA may surround an outer periphery of the display area DA.

The plurality of sub-pixels PX may be disposed in the display area DA. A light-emitting element and circuit elements for driving the light-emitting element may be disposed in each sub-pixel PX. For example, transistors and a capacitor may be included in the circuit elements. An image may be displayed in the display area DA using the plurality of sub-pixels PX. The plurality of sub-pixels PX may be arranged to be spaced apart from each other in each of a first direction DR1 and a second direction DR2 intersecting the first direction DR1 of the display area DA.

Various lines and circuits for driving the plurality of sub-pixels PX of the display area DA may be disposed in the non-display area NDA. For example, driving circuits including a gate driving circuit and a data driving circuit may be disposed in the non-display area NDA. Several drivers for driving the display area DA may be disposed in the non-display area NDA. For example, the drivers may include a gate driver and a data driver. However, embodiments of the present disclosure are not limited thereto.

The non-display area NDA may include a bonding pad area CPA in which the plurality of bonding pads 400 are disposed. The driving circuit chip package DIC may be mounted in the bonding pad area CPA. The driving circuit chip package DIC may be positioned to overlap the plurality of bonding pads 400 in a vertical direction. The chip pads of the driving circuit chip package DIC may be electrically connected to the bonding pads 400 of the display panel DP.

The printed circuit board PCB may be electrically connected to the plurality of contact and connection pads PD of the display panel DP. The control circuit chip CIC may be mounted on the printed circuit board PCB. The printed circuit board PCB may be a flexible printed circuit board. The control circuit chip CIC may control the driving circuit chip package DIC and the gate driver.

A bendable area BDA of the display panel DP may be bent to allow the printed circuit board PCB and the driving circuit chip package DIC to be disposed on a rear surface of the display area DA of the display panel DP.

The bendable area BDA may be positioned between the display panel DP and the driving circuit chip package DIC. For example, the bendable area BDA may be a portion of the non-display area NDA of the display panel DP, on which the driving circuit chip package DIC is not mounted.

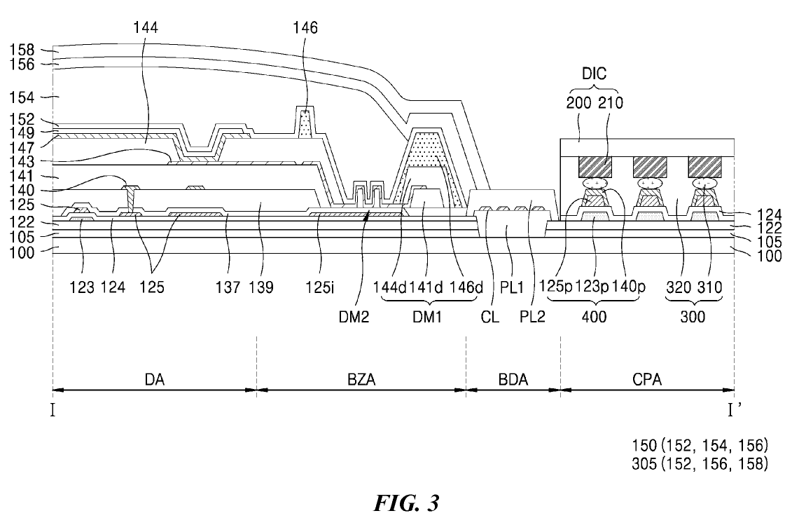

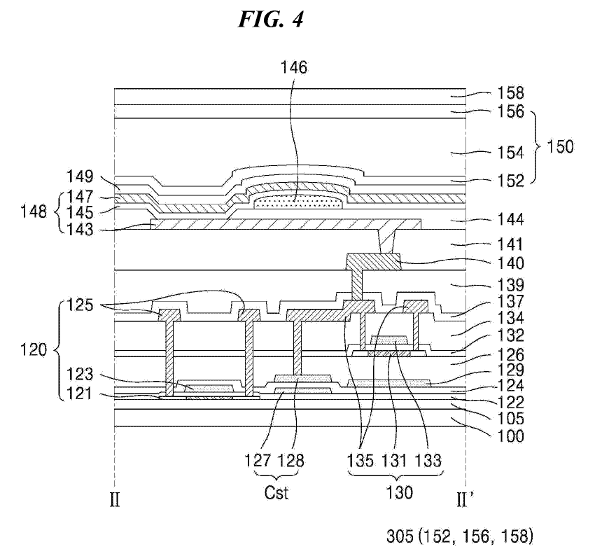

FIG. 3 is a cross-sectional view according to an embodiment of the present disclosure. FIG. 4 is a cross-sectional view taken along a line II-II′ of FIG. 2. FIG. 4 schematically illustrates one sub-pixel of a display apparatus. In the present disclosure, for convenience of illustration, one sub-pixel is illustrated. However, embodiments of the present disclosure are not limited thereto.

Referring to FIGS. 3 and 4, on a first substrate 100, a plurality of transistors 120 and 130, a capacitor Cst, and a light-emitting element 148 may be disposed. The plurality of transistors 120 and 130 may include a first transistor 120 and a second transistor 130.

One sub-pixel may include the light-emitting element 148 and a pixel driving circuit that applies a driving current to the light-emitting element 148. The pixel driving circuit is disposed on the first substrate 100, and the light-emitting element 148 is disposed on the pixel driving circuit. The pixel driving circuit may include a driving transistor, one or more switching transistors, and a capacitor. In an example, the first transistor 120 may be a switching transistor. The second transistor 130 may be a driving transistor. However, embodiments of the present disclosure are not limited thereto.

The first substrate 100 may include a glass or flexible plastic substrate. When the first substrate 100 is embodied as a plastic film, the first substrate 100 may have a structure in which multiple layers made of organic insulating material such as polyimide are stacked.

A buffer layer 105 may be disposed on the first substrate 100. The buffer layer 105 may block moisture or impurities that may extend through into the first substrate 100 from the outside. The buffer layer 105 may include an inorganic insulating material such as silicon oxide (SiOx) or silicon nitride (SiNx). The buffer layer 105 may have a single-layer or multi-layer structure.

The buffer layer 105 may extend from the display area DA into the bezel area BZA. For example, the buffer layer 105 may be disposed on the bonding pad area CPA.

The first transistor 120 may be disposed on the buffer layer 105. The first transistor 120 may include a first semiconductor layer 121, a first gate electrode 123, and a first source/drain electrode 125. In an example, the first semiconductor layer 121 may include polycrystalline silicon. However, embodiments of the present disclosure are not limited thereto.

The first semiconductor layer 121 may be disposed on the buffer layer 105. The first gate electrode 123 may be positioned to overlap the channel area of the first semiconductor layer 121. The first gate insulating layer 122 may be disposed between the first gate electrode 123 and the first semiconductor layer 121. The first gate insulating layer 122 may cover the first semiconductor layer 121. The first gate insulating layer 122 may include an inorganic insulating material such as silicon oxide (SiOx) or silicon nitride (SiNx). The first gate insulating layer 122 may extend from the display area DA into the bezel area BZA. For example, the first gate insulating layer 122 may be disposed on the bonding pad area CPA.

A light blocking layer (not shown) may be disposed between the first substrate 100 and the buffer layer 105. The light blocking layer may overlap the first semiconductor layer 121 in the vertical direction, and may be made of an opaque material. The light blocking layer may prevent the light from the outside from being incident on the first semiconductor layer 121, thereby securing reliability of the first transistor 120.

The capacitor Cst may include a first capacitor electrode 127 and a second capacitor electrode 128. The first capacitor electrode 127 may be disposed on the first gate insulating layer 122 at a position different from that of the first gate electrode 123. For example, the first capacitor electrode 127 may be made of the same material as that of the first gate electrode 123 and be formed in the same process as a process for forming the first gate electrode 123.

A metal material may be included in each of the first gate electrode 123 and the first capacitor electrode 127. For example, each of the first gate electrode 123 and the first capacitor electrode 127 may include one of molybdenum (Mo), aluminum (Al), chromium (Cr), gold (Au), titanium (Ti), nickel (Ni), neodymium (Nd), and copper (Cu), or an alloy thereof. Each of the first gate electrode 123 and the first capacitor electrode 127 may have a single layer structure or a multiple layers structure. However, embodiments of the present disclosure are not limited thereto.

A first interlayer insulating layer 124 may be disposed on the first gate electrode 123 and the first capacitor electrode 127. The first interlayer insulating layer 124 may include an inorganic insulating material such as silicon oxide (SiOx) or silicon nitride (SiNx). The first interlayer insulating layer 124 may have a single layer structure or a multiple layers structure. The first interlayer insulating layer 124 may extend from the display area DA into the bezel area BZA. For example, the first interlayer insulating layer 124 may be disposed on the bonding pad area CPA.

The second capacitor electrode 128 and a light blocking layer 129 may be disposed on the first interlayer insulating layer 124. The second capacitor electrode 128 may be made of the same material as that of the light blocking layer 129.

A metal material may be included in each of the second capacitor electrode 128 and the light blocking layer 129. For example, each of the second capacitor electrode 128 and the light blocking layer 129 may include one of molybdenum (Mo), aluminum (Al), chromium (Cr), gold (Au), titanium (Ti), nickel (Ni), neodymium (Nd), and copper (Cu), or an alloy thereof.

A second interlayer insulating layer 126 may be disposed on the second capacitor electrode 128 and the light blocking layer 129. The second transistor 130 may be disposed on the second interlayer insulating layer 126. The second transistor 130 may include a second semiconductor layer 131, a second gate electrode 133, and a second source/drain electrode 135. For example, the second transistor 130 may be disposed at a different position from that of the first transistor 120.

The second interlayer insulating layer 126 may include an inorganic insulating material such as silicon oxide (SiOx) or silicon nitride (SiNx). The second semiconductor layer 131 may be disposed on the second interlayer insulating layer 126. The second semiconductor layer 131 may include an oxide semiconductor material. The second gate electrode 133 may be positioned to overlap the channel area of the second semiconductor layer 131 in the vertical direction. The second gate insulating layer 132 may be disposed between the second gate electrode 133 and the second semiconductor layer 131. The second gate insulating layer 132 may cover the second semiconductor layer 131. The second gate insulating layer 132 may have a single layer structure or a multiple layers structure made of an inorganic insulating material such as silicon oxide (SiOx) or silicon nitride (SiNx).

A metal material may be included in the second gate electrode 133. In an example, the second gate electrode 133 may include the same material as that of the first gate electrode 123. The light blocking layer 129 may be positioned to overlap the second semiconductor layer 131 in the vertical direction. The light blocking layer 129 may prevent the light from being incident on the second semiconductor layer 131 to secure reliability of the second transistor 130.

A third interlayer insulating layer 134 may be disposed on the second gate electrode 133. The first source/drain electrode 125 and the second source/drain electrode 135 may be disposed on the third interlayer insulating layer 134. The first source/drain electrodes 125 may be electrically connected to the source/drain areas of the first semiconductor layer 121, respectively.

The first source/drain electrode 125 may extend through the third interlayer insulating layer 134, the second gate insulating layer 132, the second interlayer insulating layer 126, the first interlayer insulating layer 124, and the first gate insulating layer 122. The second source/drain electrodes 135 may be electrically connected to the source/drain areas of the second semiconductor layer 131, respectively. For example, the second source/drain electrode 135 may extend through the third interlayer insulating layer 134 and the second gate insulating layer 132.

The first source/drain electrode 125 and the second source/drain electrode 135 may be made of the same material and be formed in the same process. For example, each of the first source/drain electrode 125 and the second source/drain electrode 135 may include one of molybdenum (Mo), aluminum (Al), chromium (Cr), gold (Au), titanium (Ti), nickel (Ni), neodymium (Nd), and copper (Cu), or an alloy thereof. In an example, each of the first source/drain electrode 125 and the second source/drain electrode 135 may have a stacked structure of titanium layer/aluminum layer/titanium layer (Ti/Al/Ti).

One of the second source/drain electrodes 135 may be electrically connected to the second capacitor electrode 128 of the capacitor Cst. For example, a portion of one of the second source/drain electrodes 135 may extend through the third interlayer insulating layer 134, the second gate insulating layer 132, and the second interlayer insulating layer 126 so as to be in contact with the second capacitor electrode 128.

A signal line 125i may be disposed in the bezel area BZA. The signal line 125i may be made of the same material as that of the first source/drain electrode 125 and be formed in the same process as a process for forming the first source/drain electrode 125. The signal line 125i may transmit various signals provided from the driving circuit chip or the driver disposed on the printed circuit board to the display area DA.

A passivation layer 137 may be disposed on the first source/drain electrode 125, the second source/drain electrode 135, and the third interlayer insulating layer 134. The passivation layer 137 may include an inorganic insulating material. In an example, the passivation layer 137 may extend from the display area DA into the bezel area BZA.

A first planarization layer 139 may be disposed on the passivation layer 137. The first planarization layer 139 may planarize a step caused due to the pixel driving circuit disposed thereunder. The first planarization layer 139 may include an organic insulating material such as polyimide or acrylic resin. A pixel contact electrode 140 may be disposed on the first planarization layer 139. The pixel contact electrode 140 may extend through the first planarization layer 139 so as to directly contact the second source/drain electrode 135. The second planarization layer 141 may be disposed on the pixel contact electrode 140 and the first planarization layer 139. An organic insulating material may be included in the second planarization layer 141.

As shown in FIG. 3, the first planarization layer 139 may be disposed to extend into a partial area of the bezel area BZA. The second planarization layer 141 may be disposed to cover a sidewall of the first planarization layer 139 in the bezel area BZA.

The light-emitting element 148 may be disposed on the second planarization layer 141. The light-emitting element 148 may include a first electrode 143, a light-emitting layer 145, and a second electrode 147. The light-emitting layer 145 may be disposed between the first electrode 143 and the second electrode 147.

The light-emitting element 148 may be electrically connected to the pixel driving circuit via the pixel contact electrode 140 disposed on the first planarization layer 139. For example, the first electrode 143 of the light-emitting element 148 may be electrically connected to the second source/drain electrode 135 of the second transistor 130 via the pixel contact electrode 140.

The first electrode 143 may extend through the second planarization layer 141 so as to be connected to the pixel contact electrode 140. The pixel contact electrode 140 may extend through the first planarization layer 139 so as to directly contact the second source/drain electrode 135. In an example, the pixel contact electrode 140 may have a stacked structure of titanium layer/aluminum layer/titanium layer (Ti/Al/Ti).

The first electrode 143 may include a transparent conductive layer. For example, the first electrode 143 may include ITO (Indium Tin Oxide) or IZO (Indium Zinc Oxide). The first electrode 143 may also be referred to as an anode electrode or a pixel electrode.

A bank 144 may be disposed on the first electrode 143. The bank 144 may be disposed to cover an edge of the first electrode 143. A portion of the bank 144 may extend onto the second planarization layer 141. A portion of an upper surface of the first electrode 143 not covered with the bank 144 so as to be exposed may act as a light-emission area.

The bank 144 may include an organic insulating material. The bank 144 may include, for example, photosensitive polyimide, photoacryl, or benzocyclobutene (BCB). In an example, the bank 144 may be made of an opaque material to prevent light interference between adjacent sub-pixels. In this case, the bank 144 may include a color pigment, organic black, or carbon black.

A spacer 146 may be further disposed on the bank 144. The spacer 146 may be disposed to prevent damage to the bank 144 and the first electrode 143 during the process. The spacer 146 may be made of the same material as that of the bank 144. In this case, the spacer 146 and the bank 144 may be formed simultaneously in a single process. However, embodiments of the present disclosure are not limited thereto. In another example, the spacer 146 may be made of a material different from that of the bank 144 and be formed in a separate process from a process for forming the bank. The spacer 146 may include an organic insulating material.

The light-emitting layer 145 may be disposed on the first electrode 143. The light-emitting layer 145 may include a hole transport layer (HTL), an organic light-emitting layer (EML), an electron transport layer (ETL), a hole blocking layer (HBL), a hole injection layer (HIL), an electron blocking layer (EBL), and an electron injecting layer (EIL).

The second electrode 147 may be disposed on the light-emitting layer 145. The second electrode 147 may be formed over an entire surface of the first substrate 100 so as to be commonly connected to the light-emitting layers 145 respectively formed in all pixels. Therefore, the second electrode 147 may also be referred to as a cathode electrode or a common electrode. The second electrode 147 may include a transflective conductive material. For example, the second electrode 147 may include a metal material such as magnesium (Mg), silver (Ag), or an alloy (Ag-Mg) of silver (Ag) and magnesium (Mg).

A capping layer 149 may be disposed on the second electrode 147. The capping layer 149 may correct optical characteristics by preventing light generated from the light-emitting layer 145 from being lost.

As shown in FIG. 3, a first dam DM1 and a second dam D2 may be disposed in the bezel area BZA. The first dam DM1 may have a stacked structure in which a first layer 141d, a second layer 144d, and a third layer 146d are stacked. However, embodiments of the present disclosure are not limited thereto.

The first layer 141d of the first dam DM1 may be made of the same material as that of the second planarization layer 141 and be formed in the same process as a process for forming the second planarization layer 141. The second layer 144d may be made of the same material as that of the bank 144 and be formed in the same process as a process for forming the bank 144. The third layer 146d may be made of the same material as that of the spacer 146 and be formed in the same process as a process for forming the spacer 146. The second dam DM 2 may be disposed between the first dam DM 1 and the display area DA. The second dam DM 2 may be made of the same material as that of the second planarization layer 141 and be formed in the same process as a process for forming the second planarization layer 141. In an example, a portion of the first electrode 143 may extend from the display area DA into the bezel area BZA. The portion of the first electrode 143 extending to the bezel area BZA may cover a portion of the upper surface of the first layer 141d of the first dam DM1.

In an example, in the bendable area BDA disposed between the bezel area BZA and the bonding pad area CPA, the surface of the first substrate 100 may be in an exposed state. A first protective layer PL1 may be disposed on the exposed surface of the first substrate 100 in the bendable area BDA. The first protective layer PL1 may be disposed in the bendable area BDA and may extend into a partial area of the bezel area BZA and a partial area of the bonding pad area CPA.

A plurality of connection lines CL and a second protective layer PL2 covering the connection lines CL may be disposed on the first protective layer PL1. The connection line CL may transmit a signal provided from the driving circuit chip package DIC or the printed circuit board to the display area DA. The second protective layer PL2 may reduce stress applied to the connection line CL during the bending operation. In an example, an organic insulating material may be included in each of the first protective layer PL1 and the second protective layer PL2.

An encapsulation portion 150 may be disposed on the capping layer 149. The encapsulation portion 150 may prevent moisture or foreign substances from penetrating into the light-emitting element 148. The encapsulation portion 150 may include a first encapsulation layer 152, a second encapsulation layer 154, and a third encapsulation layer 156. The encapsulation portion 150 may be made of an inorganic material, an organic material, or a mixture of an inorganic material and an organic material, and may have a single layer structure or a multiple layers structure. For example, an inorganic insulating material such as silicon oxide (SiOx), silicon nitride (SiNx), etc., may be included in each of the first encapsulation layer 152 and the third inorganic encapsulation layer 156. The second encapsulation layer 154 may include an organic insulating material such as acryl resin, epoxy resin, phenolic resin, polyamide resin, and polyimide resin.

As shown in FIG. 3, the first encapsulation layer 152 may extend from the display area DA into the bezel area BZA. A vertical level of a top level of a side end of the second encapsulation layer 154 may be lower than a vertical level of a top level of the first dam DM1. The third encapsulation layer 156 may extend from the display area DA into the bezel area BZA.

A touch insulating layer 158 may be disposed on the third encapsulation layer 156. Although not shown in the drawing, a touch sensor array for a touch operation including a plurality of touch electrodes, touch lines electrically connecting the plurality of touch electrodes to each other, a touch protective layer protecting the touch electrodes, etc., may be disposed on the touch insulating layer 158. The touch insulating layer 158 may extend from the display area DA into the bezel area BZA. In an example, the touch insulating layer 158 may extend into a partial area of the bendable area BDA. However, embodiments of the present disclosure are not limited thereto.

The plurality of bonding pads 400 may be disposed on the bonding pad area CPA of the first substrate 100 and be arranged so as to be spaced from each other. One bonding pad 400 may include a first pad pattern 123p, a second pad pattern 125p, and a third pad pattern 140p. The first pad pattern 123p may be made of the same material as that of the first gate electrode 123 of the display area DA and be formed in the same process as a process for forming the first gate electrode 123 of the display area DA. For example, the first pad pattern 123p may include one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. The first pad pattern 123p may have a single layer structure or a multiple layers structure.

The second pad pattern 125p may be made of the same material as that of the first source/drain electrode 125 of the display area DA and be formed in the same process as a process for forming the first source/drain electrode 125 of the display area DA. The third pad pattern 140p may be made of the same material as that of the pixel contact electrode 140 of the display area DA and be formed in the same process as a process for forming the pixel contact electrode 140 of the display area DA. For example, the second pad pattern 125p or the third pad pattern 140p may have a stacked structure of titanium layer/aluminum layer/titanium layer (Ti/Al/Ti). However, embodiments of the present disclosure are not limited thereto. In an example, the third pad pattern 140p may cover an upper surface and both opposing inclined side surfaces of the second pad pattern 125p.

A stack of insulating layers may be disposed under the bonding pad 400 in the bonding pad area CPA. For example, in the bonding pad area CPA, a stack of the buffer layer 105 and the first gate insulating layer 122 may be disposed on the first substrate 100, and under the bonding pad 400. However, embodiments of the present disclosure are not limited thereto. For example, an insulating material layer other than the buffer layer 105 or the first gate insulating layer 122 may be disposed under the bonding pad 400 in the bonding pad area CPA. The first interlayer insulating layer 124 may be disposed between the first pad pattern 123p and the second pad pattern 125p in the bonding pad area CPA.

The driving circuit chip package DIC may be bonded onto the first substrate 100 of the display panel in a bonding process. A second substrate 200, a plurality of chip pads 210, and a driving circuit chip 240 may be included in the driving circuit chip package DIC. The plurality of chip pads 210 may be disposed on a rear surface of the second substrate 200.

The driving circuit chip package DIC and the display panel may be coupled (or bonded) to each other via a bonding member 300. The bonding member 300 may include a plurality of bonding structures 310 and a filler 320. The driving circuit chip package DIC and the display panel DP may be electrically connected to each other via the plurality of bonding structures 310.

The plurality of bonding structures 310 of the bonding member 300 may be respectively disposed between the chip pads 210 and the bonding pads 400. One surface of the bonding structure 310 may be in contact with the chip pad 210 and the other surface thereof may be in contact with the bonding pad 400. In an example, the other surface of the bonding structure 310 may be in contact with the third pad pattern 140p as the outermost portion of the bonding pad 400. The bonding structure 310 may include a conductive material. For example, the bonding structure 310 may include tin (Sn). The bonding structure 310 may be embodied as a conductive ball having a sphere shape. However, embodiments of the present disclosure are not limited thereto.

A space between the first substrate 100, the second substrate 200, and the bonding structure 310 may be filled with the filler 320. The filler 320 may include an organic insulating material. For example, the organic insulating material may include a resin or an epoxy-based resin. However, embodiments of the present disclosure are not limited thereto. In an example, the bonding member 300 may be embodied as an ACF (Anisotropic Conductive Film) in which the plurality of bonding structures 310 are dispersed in the filler 320. However, embodiments of the present disclosure are not limited thereto.

After the bonding member 300 has been placed between the driving circuit chip package DIC and the display panel DP, alignment marks disposed in the driving circuit chip package DIC and alignment marks disposed in the display panel DP may be respectively aligned with each other. Then, the first and second substrates may be subjected to pressing and heating such that the driving circuit chip package DIC and the display panel DP may be bonded to each other in a state in which the bonding structures 310 are pressed.

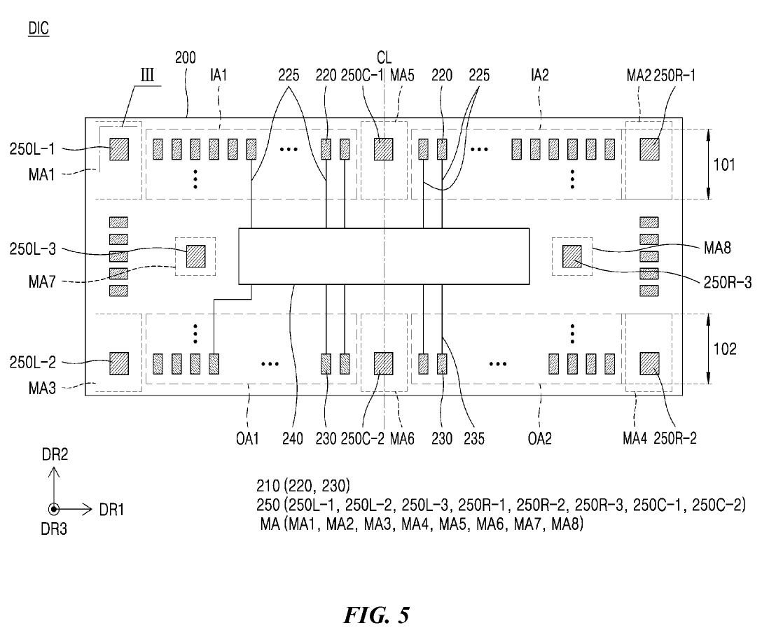

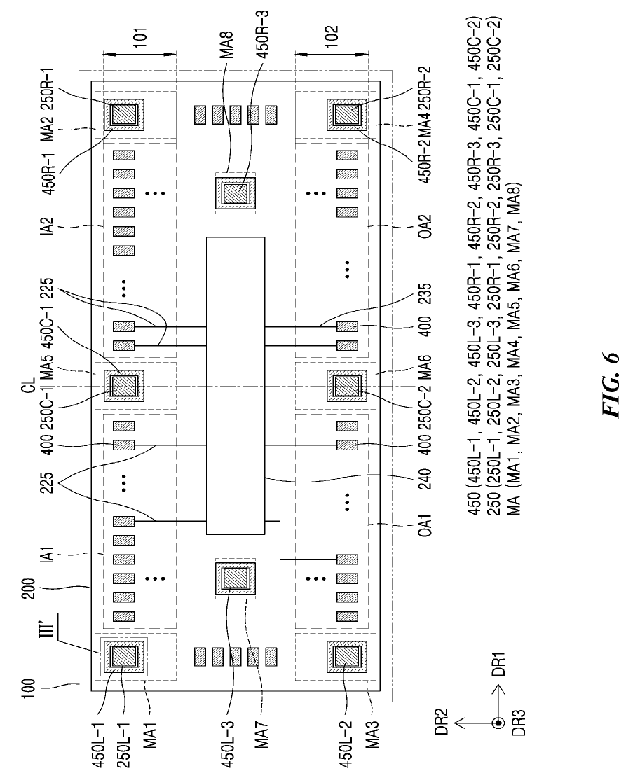

FIG. 5 is an enlarged view of a driving circuit chip package according to an embodiment of the present disclosure. FIG. 6 is a diagram illustrating a partial area in which a display panel and a driving circuit chip package are coupled to each other according to an embodiment of the present disclosure. For example, FIG. 6 illustrates a configuration in which a plurality of bonding pads disposed in the bonding pad area and a plurality of chip pads of the driving circuit chip package are respectively coupled to each other. In FIG. 6, the same reference numerals as those of FIG. 5 denote the same components as those of FIG. 5, and thus redundant descriptions thereof will be omitted or briefly set forth.

Referring to FIGS. 5 and 6, the driving circuit chip package DIC may include the second substrate 200, the plurality of chip pads 210, a first alignment mark 250, a driving circuit chip 240, and a plurality of pad lines 225 and 235. In an embodiment of the present disclosure, a configuration in which one driving circuit chip package DIC is bonded onto the display panel DP has been described by way of example. However, embodiments of the present disclosure are not limited thereto. In an example, a plurality of driving circuit chip packages DIC may be bonded onto the display panel.

The driving circuit chip package DIC may provide power or a signal supplied from the printed circuit board PCB to the light-emitting element 148 (see FIG. 4) and the circuit elements for driving the light-emitting element of the display panel DP. For example, the power or signal may include a high potential voltage, a low potential voltage, a scan signal, a data signal, etc.

The second substrate 200 may be a plastic film having flexibility. At least one driving circuit chip 240 may be included in one driving circuit chip package DIC. A first pad area 101 and a second pad area 102 may be included in an edge of the driving circuit chip package DIC. The first pad area 101 may be positioned at one side edge of the driving circuit chip package DIC, and the second pad area 102 may be opposite to the first pad area 101 and may be positioned at the other side edge of the driving circuit chip package DIC. The first and second pad areas 101 and 102 may be arranged so as to be spaced from each other in the second direction DR2.

The first pad area 101 may include a first input area IA1 and a second input area IA2. The first input area IA1 may be positioned in a left side around a center line CL in the first direction DR1 of the second substrate 200. The second input area IA2 may be positioned in a right side around the center line CL of the second substrate 200.

First chip pads 220 among the plurality of chip pads 210 may be arranged to be spaced apart from each other in the first pad area 101. In an example, the first chip pads 220 may be input pads to which a signal or power provided from the printed circuit board PCB is input.

The first chip pads 220 may be arranged to be spaced apart from each other in the first direction DR1 of the second substrate 200. In an example, the first chip pads 220 may be disposed on the rear surface of the second substrate 200. However, embodiments of the present disclosure are not limited thereto. The first direction DR1 may also be referred to as an X-axis direction, a row direction, or a longitudinal direction. The first chip pads 220 may be electrically connected to the driving circuit chip 240 via first pad lines 225. For example, a signal supplied from the printed circuit board PCB (see FIG. 1) may be transmitted to the driving circuit chip 240 via the plurality of first chip pads 220 and the first pad lines 225. The printed circuit board PCB may be electrically connected to the display panel DP via the contact and connection pad PD (see FIG. 1) of the display panel DP. The contact and connection pad PD may be electrically connected to the first chip pads 220 via lines.

The second pad area 102 may include a first output area OA1 and a second output area OA2. The first output area OA1 may be positioned in the left side around the center line CL of the second substrate 200. The second output area OA2 may be positioned in the right side around the center line CL of the second substrate 200. For example, the first output area OA1 may be aligned with and be spaced apart from the first input area IA1 in the second direction DR2 of the second substrate 200. The second output area OA2 may be aligned with and be spaced apart from the second input area IA2 in the second direction DR2 of the second substrate 200.

Second chip pads 230 among the plurality of chip pads 210 may be arranged to be spaced apart from each other in the second pad area 102. In an example, the second chip pads 230 may be output pads for outputting a signal or power converted by the driving circuit chip 123 to an external component thereto.

The second chip pads 230 may be arranged to be spaced apart from each other in the first direction DR1 of the second substrate 200. The first direction DR1 may also be referred to as an X-axis direction, a longitudinal direction, or a row direction. The second chip pads 230 may be electrically connected to the driving circuit chip 240 via second pad lines 235. For example, a signal supplied from the printed circuit board PCB (see FIG. 1) may be transmitted to the driving circuit chip 240 via the plurality of first chip pads 220 and the first pad lines 225. The driving circuit chip 240 may convert the supplied signal and provide the converted signal to the display area DA of the display panel DP via the second chip pad 230.

In an example, the plurality of chip pads 210 may also be disposed on each of both opposing edge areas in the second direction DR2 of the second substrate 200. The plurality of chip pads 210 disposed on one of both opposing edge areas in the second direction DR2 of the second substrate 200 may be electrically connected to the driving circuit chip 240 via the first pad lines. The plurality of chip pads 210 disposed on the other of both opposing edge areas in the second direction DR2 of the second substrate 200 may be electrically connected to the driving circuit chip 240 via the second pad lines.

A plurality of measurement areas MA may be defined in the second substrate 200. The plurality of measurement areas MA may be respectively disposed at least in the central area in the first direction DR1 of the second substrate 200 and in corners areas thereof in the plan view. For example, the plurality of measurement areas MA may include a first measurement area MA1, a second measurement area MA2, a third measurement area MA3, a fourth measurement area MA4, a fifth measurement area MA5, and a sixth measurement area MA6.

Among the plurality of measurement areas MA, the first measurement area MA1, the second measurement area MA2, the third measurement area MA3, and the fourth measurement area MA4 may be respectively disposed in four corner areas of the second substrate 200. The fifth measurement area MA5 may be disposed in the central area disposed between the first measurement area MA1 and the second measurement area MA2 in the first direction DR1. The sixth measurement area MA6 may be disposed in the central area disposed between the third measurement area MA3 and the fourth measurement area MA4 in the first direction. In this regard, the first measurement area MA1 and the second measurement area MA2 may be spaced from each other in the first direction and may be disposed in one of both opposing edges in the second direction DR2. The third measurement area MA3 and the fourth measurement area MA4 may be spaced from each other in the first direction and may be disposed in the other of both opposing edges in the second direction DR2.

Each of a plurality of first alignment marks 250 may be disposed in each of the plurality of measurement areas MA. The first alignment marks 250 may include a (1-1)th alignment mark 250L-1, a (1-2)th alignment mark 250R-1, a (1-3)th alignment mark 250L-2, a (1-4)th alignment mark 250R-2, a (1-5)th alignment mark 250C-1, and a (1-6)th alignment mark 250C-2. The (1-1)th alignment mark 250L-1 may be disposed on the first measurement area MA1. The (1-2)th alignment mark 250R-1 may be disposed on the second measurement area MA2. The (1-3)th alignment mark 250L-2 may be disposed on the third measurement area MA3. The (1-4)th alignment mark 250R-2 may be disposed on the fourth measurement area MA4. The (1-5)th alignment mark 250C-1 may be disposed on the fifth measurement area MA5. The (1-6)th alignment 250C-2 may be disposed on the sixth measurement area MA6.

The plurality of first alignment marks 250 may be used to measure the parallelism between the bonding tool of the bonding equipment and the backup stage opposite to and facing the bonding tool in a quantitative value. In order to improve accuracy, the plurality of first alignment marks 250 may be respectively disposed at least on the central area in the first direction DR1 of the second substrate 200 and in corners areas thereof in the plan view.

In another example, the plurality of measurement areas MA may be further disposed at positions adjacent to both opposing sides in the first direction DR1 of the driving circuit chip 240. For example, a seventh measurement area MA7 and an eighth measurement area MA8 may be included in the plurality of measurement areas MA and may be further disposed at positions adjacent to both opposing sides in the first direction DR1 of the driving circuit chip 240, respectively. In this case, a (1-7)th alignment mark 250L-3 and a (1-8)th alignment mark 250R-3 may be respectively disposed in the seventh measurement area MA7 and the eighth measurement area MA8. When the measurement areas MA7 and MA8 are further disposed at positions adjacent to both opposing sides in the first direction DR1 of the driving circuit chip 240, the accuracy of the inspection may be further improved.

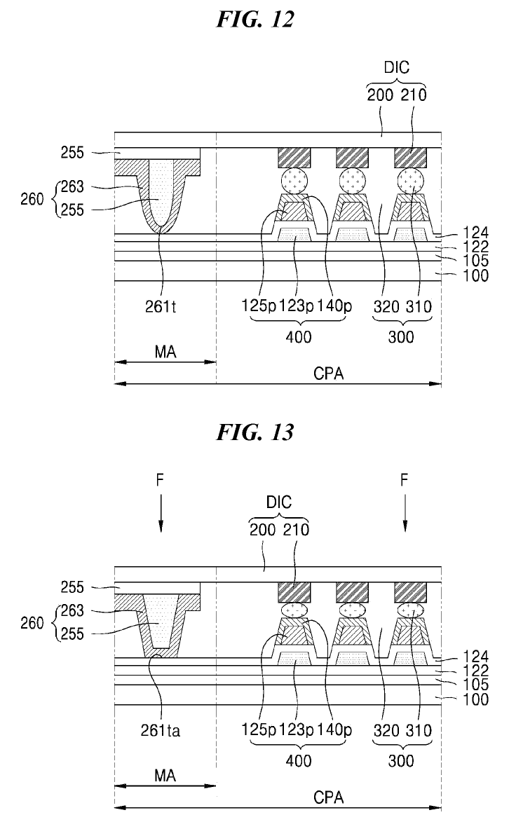

Each of the plurality of first alignment marks 250 disposed in each of the plurality of measurement areas MA may be used together with the second alignment marks disposed in the bonding pad area CPA of the display panel DP to measure the parallelism between the bonding tool and the backup stage. This will be described later with reference to FIGS. 12 and 13.

Referring to FIG. 6, the second substrate 200 of the driving circuit chip package DIC may be placed onto the first substrate 100 of the display panel DP. For example, the second substrate 200 may be placed at a position corresponding to the bonding pad area CPA of the first substrate 100. In an example, the first substrate 100 may be placed to face the rear surface of the second substrate 200. However, embodiments of the present disclosure are not limited thereto.

The plurality of bonding pads 400 and a plurality of second alignment marks 450 may be disposed on the bonding pad area CPA of the first substrate 100. Each of the bonding pads 400 may be disposed in a corresponding manner to each of the first pad area 101 and the second pad area 102 in which the plurality of chip pads 210 are disposed on the second substrate 200. For example, each of the bonding pads 400 may be disposed on each of the first input area IA1, the second input area IA2, the first output area OA1, and the second output area OA2. For example, the bonding pads 400 may be positioned to overlap the first chip pads 220 and the second chip pads 230 in the vertical direction, respectively. Accordingly, the bonding pads 400 may be arranged to be spaced apart from each other in the first direction DR1 of the first substrate 100. The first direction DR1 may also be referred to as an X-axis direction, a longitudinal direction, and a row direction.

In an example, the plurality of chip pads 210 may also be disposed on each of one edge area and the other edge area arranged in the second direction DR2 of the second substrate 200. In this case, the bonding pads 400 may also be respectively disposed on one edge area and the other edge area arranged in the second direction DR2 of the first substrate 100 so as to be bonded to the plurality of chip pads 210.

A plurality of measurement areas MA may be defined in the first substrate 100. The plurality of measurement areas MA defined in the first substrate 100 may be defined in the same manner as the manner in which the measurement areas MA are defined in the second substrate 200. That is, the first to sixth measurement areas MA defined in the first substrate 100 may overlap the first to sixth measurement areas MA defined in the second substrate 200 in the vertical direction, respectively.

The second alignment mark 450 may be disposed on each of the plurality of measurement areas MA. The second alignment marks 450 may include a (2-1)th alignment mark 450L-1, a (2-2)th alignment mark 450R-1, a (2-3)th alignment mark 450L-2, a (2-4)th alignment mark 450R-2, a (2-5)th alignment mark 450C-1, and a (2-6)th alignment mark 450C-1. When the seventh measurement area MA7 and the eighth measurement area MA8 are included in the plurality of measurement areas MA, a (2-7)th alignment mark 450L-3 and a (2-8)th alignment mark 250R-3 respectively corresponding to the (1-7)th alignment mark 250L-3 and the (1-8)th alignment mark 250R-3 may be defined in the first substate 100.

Each of the second alignment marks 450 may be disposed to correspond to each of the first alignment marks 250. Each second alignment mark 450 may have a quadrilateral ring shape in which an empty space is defined. Each first alignment mark 250 may be positioned to overlap the empty space defined in each second alignment mark 450 in the vertical direction. That is, in the plan view, the second alignment mark 450 may have a shape surrounding the outer periphery of the first alignment mark 250.

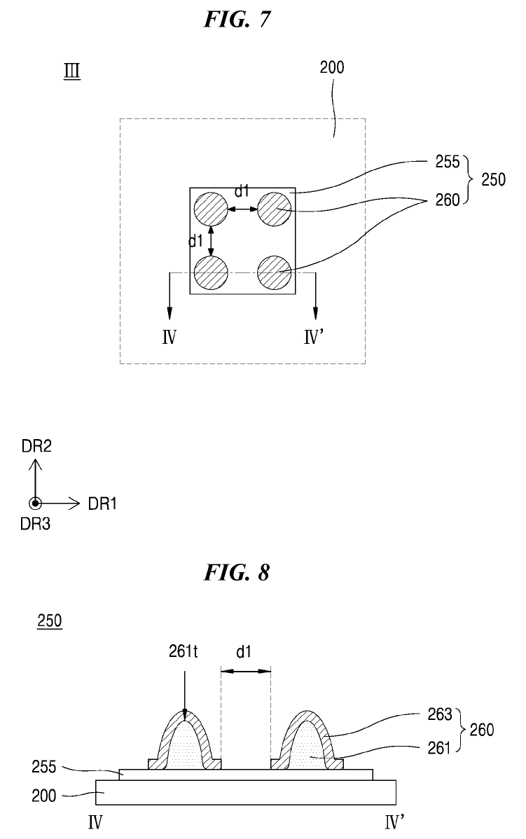

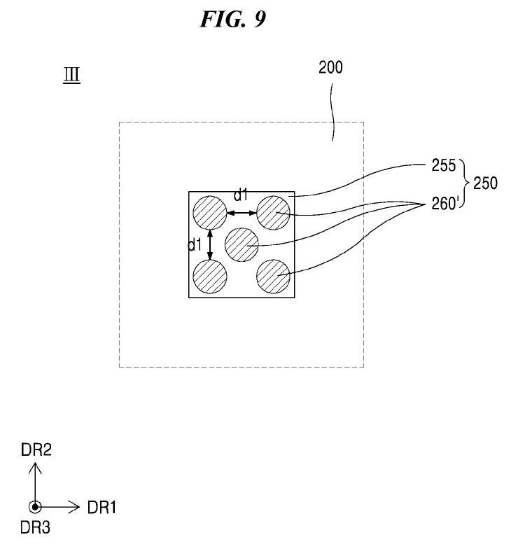

FIGS. 7 and 8 are diagrams illustrating a first alignment mark according to one embodiment of the present disclosure. For example, FIG. 7 illustrates one first alignment mark among the plurality of first alignment marks. FIG. 8 is a cross-sectional view taken along a line IV-IV′ of FIG. 7. FIG. 9 is a diagram illustrating a first alignment mark according to another embodiment of the present disclosure. In FIG. 9, the same reference numerals as those of FIG. 7 denote the same components as those in FIG. 7, and thus redundant descriptions thereof will be omitted or briefly set forth.

Referring to FIGS. 7 and 8, the first alignment mark 250 may include an alignment plate 255 and a plurality of protruding patterns 260. The alignment plate 255 may be disposed on the second substrate 200. The alignment plate 255 may be referred to as a support substrate that supports the plurality of protruding patterns 260 while being disposed thereunder. The alignment plate 255 may have a polygonal shape in the plan view. For example, the alignment plate 255 may be formed in a quadrilateral shape in the plan view. A plurality of protruding patterns 260 may be disposed on the alignment plate 255. However, embodiments of the present disclosure are not limited thereto. For example, the plurality of protruding patterns 260 may be directly disposed on the second substrate 200.

Each of the plurality of protruding patterns 260 may be disposed at each corner area of the alignment plate 255. The neighboring protruding patterns 260 may be arranged to be spaced apart from each other by a first distance d1. For example, the first distance d1 in the first direction DR1 of the alignment plate 255 may be equal to the first distance d1 in the second direction DR2 thereof. A spacing between the protruding patterns 260 adjacent to each other in the diagonal direction may be greater than the first distance d1.

Referring to FIG. 8, the plurality of protruding patterns 260 may protrude from an upper surface of the alignment plate 255 in a thickness direction thereof. Each of the plurality of protruding patterns 260 may include a protrusion 261 and a cover layer 263. A bottom surface of the protrusion 261 may be in contact with the upper surface of the alignment plate 255.

The uppermost end 261t of the protrusion 261 may include a curvature shape in the cross-sectional view. For example, the uppermost end 261t of the protrusion 261 may have a rounded shape in the cross-sectional view. The cover layer 263 may cover the protrusion 261. For example, the cover layer 263 may be disposed to cover the surface of the protrusion 261 so as not to be exposed. A portion of the cover layer 263 may extend along and on the upper surface of the alignment plate 255. When being viewed in a plan view, the protrusion 261 may have a circular shape, as shown in FIG. 7.

The protrusion 261 may include an organic insulating material. For example, the protrusion 261 may include acrylic resin, polyimide, or polystyrene. The cover layer 263 may include a metal material. For example, the cover layer 263 may include a metal material having ductility. For example, the metal material having ductility may include gold (Au). However, embodiments of the present disclosure are not limited thereto.

The protrusion 261 may include a material having greater rigidity relative to that of the cover layer 263. The protrusion 261 may function as a compression suppression point capable of preventing the cover layer 263 from being excessively spread during a bonding operation.

In another example, each of the plurality of protruding patterns 260 may be composed only of the protrusion 261. In this case, the protrusion 261 may include an opaque material so as to be observed by a microscope.

Referring to FIG. 9, the first alignment mark 250 may include the alignment plate 255 and a plurality of protruding patterns 260′. The plurality of protruding patterns 260′ may include each protruding pattern disposed on each corner area of the alignment plate 255 and a protruding pattern disposed on a central area of the alignment plate 255. Accordingly, five protruding patterns 260′ may be disposed on the alignment plate 255. Adjacent ones of the protruding patterns 260′ respectively disposed on the corner areas may be spaced apart from each other by a first distance d1. For example, the first distance d1 in the first direction DR1 of the alignment plate 255 may be equal to the first distance d1 in the second direction DR2 of the alignment plate 255. For example, the first direction DR1 may be a row or longitudinal direction, and the second direction DR2 may be a column or transverse direction. A spacing between the protruding patterns 260′ adjacent to each other in the diagonal direction may be smaller than the first distance d1.

The number of protruding patterns 260 constituting the first alignment mark 250 may be four or five. When the number of the plurality of protruding patterns 260 is smaller than four, there is a high possibility that an error due to deposition deviation of the protruding patterns 260 occurs. Accordingly, the reliability of the inspection may be deteriorated. In addition, when the number of the plurality of protruding patterns 260 exceeds five, a greater number of the protruding patterns 260 should be disposed within the limited area of the alignment plate 255. In this case, a diameter of each protruding pattern 260 should be reduced for the arrangement of the protruding patterns. In this regard, a change in a size of the protruding pattern 260 to which a pressure is applied during the bonding process is not large, such that it may be difficult to achieve accurate measurement. Accordingly, the reliability of the inspection may be deteriorated, and defects may occur. Accordingly, it is preferable that the number of the plurality of protruding patterns 260 constituting the first alignment mark 250 is at least four and is not greater than five.

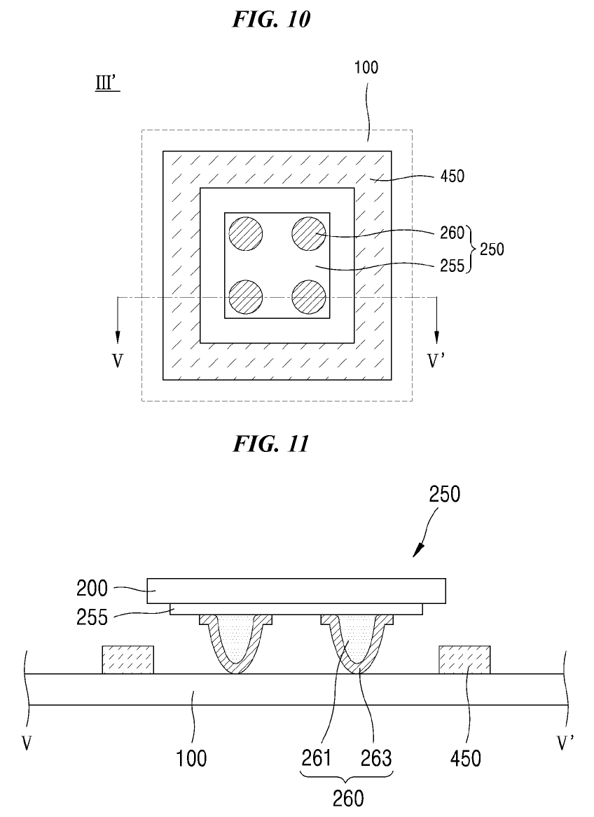

FIGS. 10 and 11 are enlarged views of an area III′ of FIG. 6. In FIG. 10, the second substrate 200 is omitted for convenience of illustration. FIGS. 12 and 13 are diagrams illustrating a display apparatus before and after a bonding process of a first substrate and a second substrate to each other according to an embodiment of the present disclosure. In FIGS. 12, 13, and 6, the same reference numerals may denote the same components.

Referring to FIGS. 6, 10, and 11, together with each other, the first substrate 100 and the second substrate 200 may overlap each other in the vertical direction in a bonding process. Accordingly, the first alignment mark 250 may be positioned in the inner space of the second alignment mark 450 in the plan view. That is, the first alignment mark 250 may be positioned so as to be surrounded with the second alignment mark 450 in the plan view

For example, the surface of the first substrate 100 may be exposed in the inner space of the second alignment mark 450. The cover layer 263 of the first alignment mark 250 may be in contact with the exposed surface of the first substrate 100. However, embodiments of the present disclosure are not limited thereto. For example, a multi-layered insulating material stack may be disposed on a partial area of the first substrate 100 onto which the first alignment mark 250 is placed. For example, the multi-layered insulating material stack may include the buffer layer 105, the first gate insulating layer 122, and the first interlayer insulating layer 124. However, embodiments of the present disclosure are not limited thereto.

The bonding process may include a pre-pressing process and a main pressing process. For example, the pre-pressing process may be a process step of positioning the second substrate 200 onto the bonding pad area CPA of the first substrate 100 at a low temperature, as shown in FIG. 12. In the pre-pressing process, the first alignment mark 250 may be positioned on the measurement area MA in the bonding pad area CPA of the first substrate 100. In the pre-pressing process, the shape of the uppermost end 261t of the first alignment mark 250 may not be deformed. For example, the uppermost end 261t of the first alignment mark 250 may have the round shape in the cross-sectional view.

As shown in FIG. 13, the main pressing process may be a process step of actually applying heating and pressure to bond the second substrate 200 onto the first substrate 100. In the main pressing process, as the first alignment mark 250 is pressed by a pressure F, the uppermost end 261t of the first alignment mark 250 may be deformed into a flat surface 261ta.

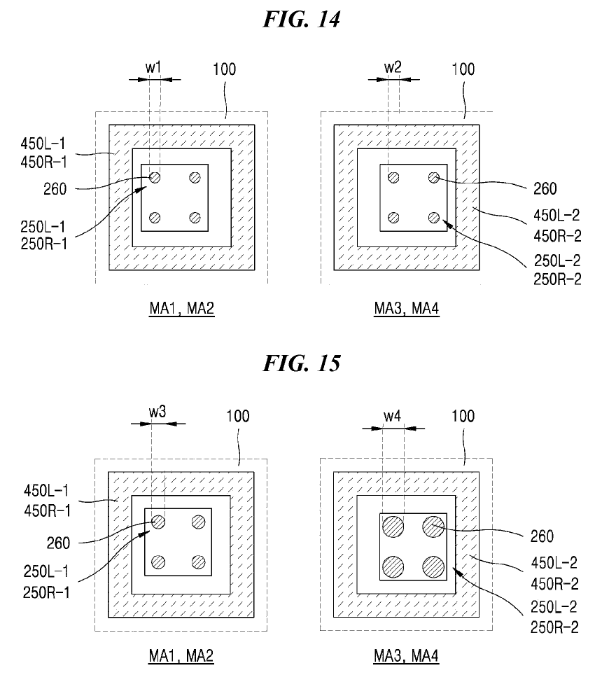

The parallelism between the bonding tool and the backup stage may be measured and evaluated after the main pressing process. For example, the parallelism between the bonding tool and the backup stage may be evaluated by measuring a diameter of the flat surface 261ta of the first alignment mark 250 and comparing the diameters before and after the pressing with each other. This will be described later with reference to FIGS. 14 and 15.

Accordingly, it is preferable that the overall height of the first alignment mark 250 is formed in consideration of the height measured after the main pressing process. For example, the overall height of the first alignment mark 250 may be a second height which may be smaller than or equal to a first height as the total sum of a height of the chip pad 210, a thickness (or diameter) of the bonding structure 310, and a height of the bonding pad 400. When the overall height of the second alignment mark 450 is a third height greater than the first height, the pressing quality may be affected. For example, the pressing may be stopped at a vertical level relatively lower than a target vertical level. Thus, the chip pad 210 and the bonding pad 400 are not properly bonded to each other, and thus a contact and connection failure may occur.

FIGS. 14 and 15 are diagrams illustrating a scheme of measuring a parallelism using alignment marks according to an embodiment of the present disclosure. In FIGS. 14, 15, and 6, the same reference numerals may denote the same components.

FIG. 14 shows a bonding process performed at a first pressure, and FIG. 15 shows a bonding process performed at a second pressure greater than the first pressure. FIGS. 14 and 15 respectively measure the alignment marks disposed on the first measurement area MA1, the second measurement area MA2, the third measurement area MA3, and the fourth measurement area MA4 of the corner areas of the second substrate 200. For example, referring to FIGS. 14 and 15 together with FIG. 6, the first measurement area MA1 may be positioned at a first corner area of one side in the first direction DR1 and one side in the second direction DR2 of the second substrate 200, and the second measurement area MA2 may be positioned at a second corner area of the other side in the first direction DR1 and one side in the second direction DR2 of the second substrate 200. In each of the first measurement area MA1 and the second measurement area MA2, each of the (1-1)th alignment mark 250L-1 and the (1-2)th alignment mark 250R-1 may be positioned to overlap the inner space of each of the (2-1)th alignment mark 450L-1 and the (2-2)th alignment mark 450R-1 in the vertical manner.

In addition, the third measurement area MA3 may be positioned at a third corner area of one side in the first direction DR1 and the other side in the second direction DR2 of the second substrate 200. The fourth measurement area MA4 may be positioned at a fourth corner area of the other side in the first direction DR1 and the other side in the second direction DR2 of the second substrate 200. In each of the third measurement area MA3 and the fourth measurement area MA4, each of the (1-3)th alignment mark 250L-2 and the (1-4)th alignment mark 250R-2 may be positioned to overlap the inner space of each of the (2-3)th alignment mark 450L-2 and the (2-4)th alignment mark 450R-2 in the vertical manner.

Referring to FIG. 14, after the main pressing process is performed at the first pressure, the diameter size of the protrusion pattern 260 of each of the (1-1)th alignment mark 250L-1 and the (1-2) alignment mark 250R-1 may be measured as a first width w1, and the diameter size of the protrusion pattern 260 of each of the (1-3)th alignment mark 250L-2 and the (1-4)th alignment mark 250R-2 may be measured as a second width w2. The first width w1 and the second width w2 may be automatically measured using a microscope algorithm. Each of the first width w1 and the second width w2 may be derived by measuring the respective diameter sizes of the plurality of protruding patterns 260 and calculating an average value thereof.

In response to that the difference between the first width w1 and the second width w2 in the pressing process at the first pressure does not deviate from a set size range, the parallelism between the bonding tool and the backup stage may be evaluated as being maintained within the set range.

Referring to FIG. 15, after the main pressing process is performed at the second pressure greater than the first pressure, the diameter size of the protrusion pattern 260 of each of the (1-1)th alignment mark 250L-1 and the (1-2)th alignment mark 250R-1 may be measured to have a third width w3, and the diameter size of the protrusion pattern 260 of each of the (1-3)th alignment mark 250L-2 and the (1-4)th alignment mark 250R-2 may be measured to have a fourth width w4.

In response to that the difference between the third width w3 and the fourth width w4 in the pressing process at the second pressure is out of the set size range, the parallelism between the bonding tool and the backup stage may be evaluated as not being maintained within the set range, that is, the interface of the bonding tool and the backup stage may be tilted to the left or right side. In this case, the tilt of the bonding tool may be adjusted such that the parallelism between the bonding tool and the backup stage is maintained within the set range.

In another example, the parallelism between the bonding tool and the backup stage may be measured and evaluated not only using the diameter size of the protruding pattern 260 but also using the spacing between the first alignment mark 250 and the second alignment mark 450.

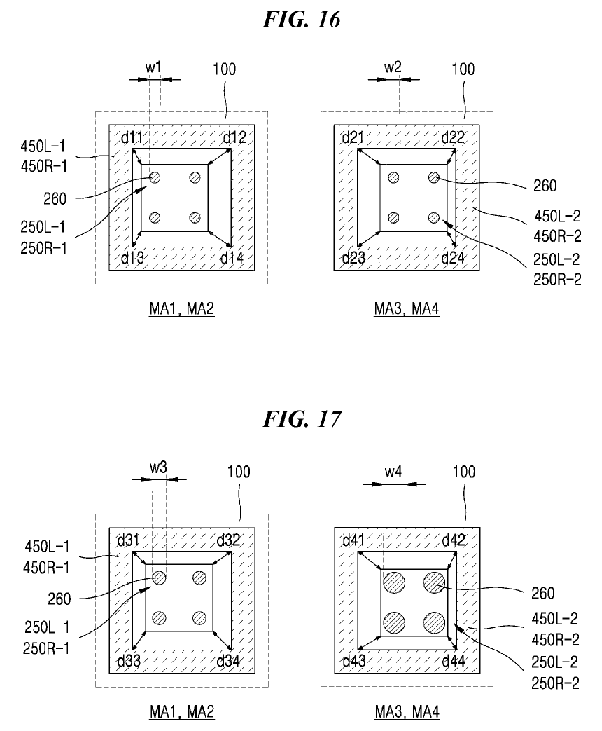

FIGS. 16 and 17 are diagrams illustrating a parallelism measurement scheme using alignment marks according to another embodiment of the present disclosure. FIGS. 16 and 17 differ from FIGS. 14 and 15 in that in FIGS. 16 and 17, the parallelism between the bonding tool and the backup stage is measured and evaluated using the spacing between the first alignment mark 250 and the second alignment mark 450. In FIGS. 15 and 17,14, and 15, the same reference numerals may denote the same components.

Referring to FIGS. 16 and 17, after performing the main pressing process at each of the first pressure and the second pressure, the first to fourth diameters w1, w2, w3, and w4 of the protruding pattern 260 may be measured. In response to that the difference between the first width w1 and the second width w2 in the pressing process at the first pressure does not deviate from a set size range, the parallelism between the bonding tool and the backup stage may be evaluated as being maintained within the set range. In response to that the difference between the third width w3 and the fourth width w4 in the pressing process at the second pressure is out of the set size range, the parallelism between the bonding tool and the backup stage may be evaluated as not being maintained within the set range, that is, the interface of the bonding tool and the backup stage may be tilted to the left or right side. In this case, the tilt of the bonding tool may be adjusted such that the parallelism between the bonding tool and the backup stage is maintained within the set range.

In addition, the parallelism between the bonding tool and the backup stage may be measured and evaluated via the spacing between the first alignment mark 250 and the second alignment mark 450. For example, referring to FIG. 16, after the main pressing process is performed at the first pressure, respective first gaps d11, d12, d13, and d14 between the corner areas of the alignment plate 255 of each of the (1-1)th alignment mark 250L-1 and the (1-2)th alignment mark 250R-1 and the corner areas of the inner space of each of the (2-1)th alignment mark 450L-1 and the (2-2)th alignment mark 450R-1 may be measured. Respective second gaps d21, d22, d23, and d24 between the corner areas of the alignment plate 255 of each of the (1-3)th alignment mark 250L-2 and the (1-4)th alignment mark 250R-2 and the corner areas of the inner space of the (2-3)th alignment mark 450L-2 and the (2-4)th alignment mark 450R-2 may be measured.

In response to that the difference between each of the first gaps d11, d12, d13, and d14 and the corresponding one of the second gaps d21, d22, d23, and d24 in the main pressing process at the first pressure does not exceed the set size range, the parallelism between the bonding tool and the backup stage may be evaluated as being maintained within the set range.

Referring to FIG. 17, third gaps d31, d32, d33, and d34 and fourth gaps d41, d42, d43, and d44 may be measured after the main processing process is performed at the second pressure greater than the first pressure. Specifically, respective third gaps d31, d32, d33, and d34 between the corner areas of the alignment plate 255 of each of the (1-1)th alignment mark 250L-1 and the (1-2)th alignment mark 250R-1 and the corner areas of the inner space of each of the (2-1)th alignment mark 450L-1 and the (2-2)th alignment mark 450R-1 may be measured. Respective fourth gaps d41, d42, d43, and d44 between the corner areas of the alignment plate 255 of each of the (1-3)th alignment mark 250L-2 and the (1-4)th alignment mark 250R-2 and the corner areas of the inner space of each of the (2-3)th alignment mark 450L-2 and the (2-4)th alignment mark 450R-2 may be measured.

In this regard, in response to that the difference between each of the third gaps d31, d32, d33, and d34 and the corresponding one of the fourth gaps d41, d42, d43, and d44 exceeds the set size range, the parallelism between the bonding tool and the backup stage may be evaluated as not being maintained within the set range, that is, the interface between the bonding tool and the backup stage may be tilted to the left or right side. In this case, the tilt of the bonding tool may be adjusted such that the parallelism between the bonding tool and the backup stage is maintained within the set range.

The display apparatus according to various aspects and embodiments of the present disclosure may be described as follows.

One aspect of the present disclosure provides a display apparatus comprising: a first substrate including a display area and a non-display area disposed outside the display area; a bonding pad area disposed in the non-display area; a second substrate disposed on the bonding pad area of the first substrate; a first alignment mark disposed on the second substrate; and a second alignment mark disposed on the bonding pad area of the first substrate and positioned to overlap the first alignment mark in a vertical direction, wherein the first alignment mark includes a plurality of protruding patterns.

In accordance with some embodiments of the present disclosure, the first alignment mark is disposed on at least each of corner areas of the second substrate in a plan view thereof.

In accordance with some embodiments of the present disclosure, the first alignment mark is disposed on a center line of the second substrate in a plan view thereof.

In accordance with some embodiments of the present disclosure, the first alignment mark further includes an alignment plate disposed under the plurality of protruding patterns.

In accordance with some embodiments of the present disclosure, the plurality of protruding patterns are disposed at least on corner areas of the alignment plate, respectively in a plan view thereof.

In accordance with some embodiments of the present disclosure, one of the plurality of protruding patterns is disposed on a central area of the alignment plate in a plan view thereof.

In accordance with some embodiments of the present disclosure, a number of the plurality of protruding patterns is four or five.

In accordance with some embodiments of the present disclosure, each of the plurality of protruding patterns includes a protrusion having an end facing the first substrate and having a flat surface shape.

In accordance with some embodiments of the present disclosure, each of the plurality of protruding patterns further includes a cover layer covering the protrusion.

In accordance with some embodiments of the present disclosure, the protrusion includes a material having a relatively greater rigidity than a rigidity of the cover layer, wherein the cover layer includes a metal material having ductility.

In accordance with some embodiments of the present disclosure, the protruding patterns disposed on the corner areas of the alignment plate and adjacent to each other in a column direction or a row direction of the alignment plate in the plan view are spaced apart from each other by a first distance, wherein the protruding patterns disposed on the alignment plate and adjacent to each other in a diagonal direction of the alignment plate in the plan view are spaced apart from each other by a second distance greater than the first distance.

In accordance with some embodiments of the present disclosure, the protruding patterns disposed on the corner areas of the alignment plate and adjacent to each other in a column direction or a row direction of the alignment plate in the plan view are spaced apart from each other by a first distance, wherein the protruding patterns disposed on the alignment plate and adjacent to each other in a diagonal direction of the alignment plate in the plan view are spaced apart from each other by a second distance smaller than the first distance.

In accordance with some embodiments of the present disclosure, in a plan view, the second alignment mark has a quadrilateral ring shape having an empty space defined therein, wherein the first alignment mark is positioned to be received in the empty space.

In accordance with some embodiments of the present disclosure, the display apparatus further comprises: a plurality of bonding pads disposed on the bonding pad area and spaced from the second alignment mark; a plurality of chip pads disposed on the second substrate so as to respectively overlap and face the plurality of bonding pads in the vertical direction; a plurality of bonding structures respectively disposed between the plurality of bonding pads and the plurality of chip pads; and a filler filling a space defined between the first substrate, the second substrate, and the bonding structure in the bonding pad area.

In accordance with some embodiments of the present disclosure, a height of the first alignment mark is smaller than or equal to a total sum of a height of the chip pad, a height of the bonding structure, and a height of the bonding pad.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a first substrate including a display area and a non-display area disposed outside the display area;
a bonding pad area disposed in the non-display area;
a second substrate disposed on the bonding pad area of the first substrate;
a first alignment mark disposed on the second substrate; and
a second alignment mark disposed on the bonding pad area of the first substrate and positioned to overlap the first alignment mark in a vertical direction,
wherein the first alignment mark includes a plurality of protruding patterns.

2. The display apparatus of claim 1, wherein the first alignment mark is disposed on at least each of corner areas of the second substrate in a plan view thereof.

3. The display apparatus of claim 1, wherein the first alignment mark is disposed on a center line of the second substrate in a plan view thereof.

4. The display apparatus of claim 1, wherein the first alignment mark further includes an alignment plate disposed under the plurality of protruding patterns.

5. The display apparatus of claim 4, wherein the plurality of protruding patterns are disposed at least on corner areas of the alignment plate, respectively in a plan view thereof.

6. The display apparatus of claim 5, wherein one of the plurality of protruding patterns is disposed on a central area of the alignment plate in a plan view thereof.

7. The display apparatus of claim 1, wherein a number of the plurality of protruding patterns is at least four.

8. The display apparatus of claim 1, wherein a number of the plurality of protruding patterns is five or less.

9. The display apparatus of claim 1, wherein each of the plurality of protruding patterns includes a protrusion having an end facing the first substrate and having a flat surface shape.

10. The display apparatus of claim 9, wherein each of the plurality of protruding patterns further includes a cover layer covering the protrusion.

11. The display apparatus of claim 10, wherein the protrusion includes a material having a relatively greater rigidity than a rigidity of the cover layer, and
wherein the cover layer includes a metal material having ductility.

12. The display apparatus of claim 5, wherein the plurality of protruding patterns disposed on the corner areas of the alignment plate and adjacent to each other in a column direction or a row direction of the alignment plate in the plan view are spaced apart from each other by a first distance, and
wherein the protruding patterns disposed on the alignment plate and adjacent to each other in a diagonal direction of the alignment plate in the plan view are spaced apart from each other by a second distance greater than the first distance.

13. The display apparatus of claim 6, wherein the protruding patterns disposed on the corner areas of the alignment plate and adjacent to each other in a column direction or a row direction of the alignment plate in the plan view are spaced apart from each other by a first distance, and
wherein the protruding patterns disposed on the alignment plate and adjacent to each other in a diagonal direction of the alignment plate in the plan view are spaced apart from each other by a second distance smaller than the first distance.

14. The display apparatus of claim 1, wherein in a plan view, the second alignment mark has a quadrilateral ring shape having an empty space defined therein, and
wherein the first alignment mark is positioned to be received in the empty space.

15. The display apparatus of claim 1, wherein the display apparatus further comprises:
a plurality of bonding pads disposed on the bonding pad area and spaced from the second alignment mark;
a plurality of chip pads disposed on the second substrate so as to respectively overlap and face the plurality of bonding pads in the vertical direction;
a plurality of bonding structures respectively disposed between the plurality of bonding pads and the plurality of chip pads; and
a filler extending into a space defined between the first substrate, the second substrate, and the plurality of bonding structures in the bonding pad area.

16. The display apparatus of claim 15, wherein a height of the first alignment mark is smaller than or equal to a total sum of a height of one of the plurality of chip pads, a height of one of the plurality of bonding structures, and a height of one of the plurality of bonding pads.
